(19) United States
(12) Patent Application Publication
(10) Pub. No.: US 2009/0283856 A1
(43) Pub. Date: Nov. 19, 2009

(54) METHOD FOR FABRICATING A SEMICONDUCTOR CAPACITPR DEVICE

(76) Inventors: Tsai-Yu Huang, Taipei County (TW); Shin-Yu Nieh, Taipei City (TW); Chun-I Hsieh, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 12/167,239

(22) Filed: Jul. 2, 2008

(30) Foreign Application Priority Data
May 13, 2008 (TW) 097117600

(51) Int. Cl. H01L 29/94

(52) U.S. Cl. 257/532; 257/E29.345

(57) ABSTRACT

A method for fabricating a semiconductor capacitor includes a substrate having thereon a carbon electrode. A transitional barrier layer is then deposited on the carbon electrode layer. Thereafter, a metal oxide layer is deposited on the transitional barrier layer, which reacts with the underlying transitional barrier layer to form a metal oxy-nitride layer acting as a capacitor dielectric layer of the capacitor device. A top electrode layer is then formed on the metal oxy-nitride layer.

### BACKGROUND OF THE INVENTION

1. Field of the Invention

The present invention relates generally to a method for fabricating a semiconductor capacitor device. More particularly, this invention relates to a method for fabricating a high dielectric constant (high-k) capacitor dielectric layer on a surface of a carbon electrode of a semiconductor capacitor device.

2. Description of the Prior Art

Carbon has been proposed as a promising FEOL (front-end of line) material with high conductivity and thermal stability for the fabrication of the advanced semiconductor memory devices. The applications of carbon-based electrodes for future DRAM cell capacitors may include metal-insulator-carbon (MIC) capacitors, carbon-insulator-carbon (CIC) capacitors, and polysilicon-insulator-carbon (SIC) capacitors. The combination of carbon-based electrode and high-k dielectrics such as HfO₂ can increase capacitance and reliability of the memory devices.

However, there are major challenges of integrating the aforesaid advanced materials including carbon and the high-k metal oxide materials with the front-end of line semiconductor fabrication processes. For example, in order to fabricate a high-quality, high-k metal oxide, ozone is required during the deposition of the high-k metal oxide. Unfortunately, ozone also corrodes the carbon electrode formed on the surface of a semiconductor substrate. Therefore, there is a strong need in this industry to provide an improved method for fabricating a high-quality, high-k metal oxide on a carbon electrode without adversely affecting the carbon electrode.

### SUMMARY OF THE INVENTION

It is one objective of the preferred embodiment to provide an improved method for fabricating a high-quality, high-k metal oxide on a carbon electrode in order to solve the above-mentioned prior art problems.

To these ends, according to one aspect of the preferred embodiment, there is provided a method for fabricating a semiconductor capacitor device including the steps of providing a substrate; forming a bottom electrode layer on the substrate; performing a first deposition process to deposit a transitional barrier layer on a surface of the bottom electrode layer; performing a second deposition process to deposit a metal oxide layer on the transitional barrier layer, wherein the transitional barrier layer reacts with the metal oxide layer to form a capacitor dielectric layer; and forming a capacitor top electrode on the capacitor dielectric layer.

In another aspect, according to the second preferred embodiment of this invention, there is provided a method for fabricating a semiconductor capacitor device including the steps of providing a substrate; forming a bottom electrode layer on the substrate; depositing a dielectric layer on a surface of the bottom electrode layer; performing an atomic layer deposition process to deposit a metal oxide layer on the dielectric layer; and forming a capacitor top electrode on the metal oxide layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 5 are schematic, cross-sectional diagrams showing a method for fabricating a semiconductor capacitor device in accordance with the first preferred embodiment of this invention.

FIG. 6 to FIG. 9 are schematic, cross-sectional diagrams showing a method for fabricating a semiconductor capacitor device in accordance with the second preferred embodiment of this invention.

### DETAILED DESCRIPTION

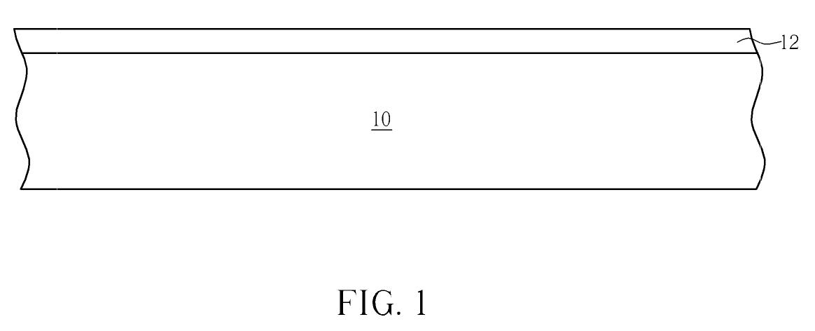

Please refer to FIG.1 to FIG. 5. FIG. 1 to FIG. 5 are schematic, cross-sectional diagrams showing a method for fabricating a semiconductor capacitor device in accordance with the first preferred embodiment of this invention. As shown in FIG. 1, a substrate 10 such as a silicon substrate is provided. A carbon electrode layer 12 is formed on the substrate 10. The carbon electrode layer 12 acts as a bottom capacitor electrode according to the first preferred embodiment. It is understood that other dielectric layers or devices may be formed on the substrate 10. For the sake of simplicity, these dielectric layers or devices are omitted. The carbon electrode layer 12 may be formed by conventional methods, for example, furnace techniques utilizing ethylene (C₂H₄) as a precursor. The carbon electrode layer 12 is composed of carbon atoms bonded in a conductive manner such as SP2 hybrid orbital bonds. Preferably, the carbon electrode layer 12 has a thickness of about 1 nm-1000 nm.

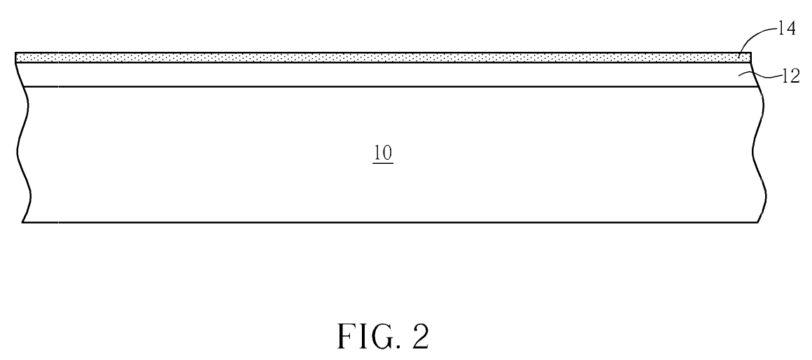

As shown in FIG. 2, after the formation of the carbon electrode layer 12 on the substrate 10, a deposition process such as an atomic layer deposition (hereinafter “ALD”) process is carried out to deposit a transitional barrier layer 14 on the surface of the carbon electrode layer 12. It is important to cover the entire surface of the carbon electrode layer 12 with the transitional barrier layer 14. According to the first preferred embodiment of this invention, the transitional barrier layer 14 is composed of metal nitride including but not limited to aluminum nitride, tantalum nitride, titanium nitride, zirconium nitride, hafnium nitride, lanthanum nitride and cerium nitride. The transitional barrier layer 14 may be formed by conventional ALD methods.

Taking hafnium nitride as an example, in order to completely cover the surface of the carbon electrode layer 12 with the transitional barrier layer 14, 3 to 5 ALD cycles is ordinarily required to deposit a hafnium nitride layer having an adequate thickness of 1.8 angstroms to 3.0 angstroms over the carbon electrode layer 12 (0.6 angstroms per ALD cycle). On the other hand, however, it is not desired to deposit a hafnium nitride layer that is too thick for fear of incomplete reaction of the hafnium nitride layer with the subsequently deposited metal oxide. Accordingly, the hafnium nitride layer over the carbon electrode layer 12 is preferably deposited in less than 10 ALD cycles.

Typically, each of the aforesaid ALD cycles for depositing the transitional barrier layer 14 includes four sequential stages: (1) flowing organic metal precursor into the reactor for a period of time to adsorb the organic metal precursor on the surface of the substrate; (2) purging the excess organic metal precursor out of the reactor using inert gas such as argon; (3) flowing ammonia into the reactor to react the ammonia with the organic metal precursor adsorbed on the substrate to form a metal nitride layer; and (4) purging the reactor again with inert gas such as argon. The subsequent ALD cycles repeat the four sequential stages.

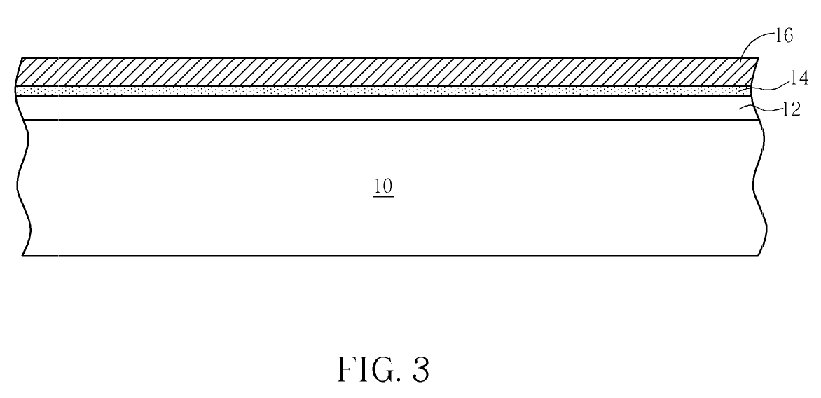

As shown in FIG. 3, after the deposition of the transitional barrier layer 14 on the carbon electrode layer 12, an ALD process is performed to deposit a metal oxide layer 16 such as aluminum oxide, tantalum oxide, titanium oxide, zirconium oxide, hafnium oxide, lanthanum oxide or cerium oxide on the surface of the transitional barrier layer 14. The metal oxide layer 16 has high dielectric constant such that the metal oxide layer 16 can function as a capacitor dielectric layer. By way of example, the metal oxide layer 16 is hafnium oxide (HfO₂) having a dielectric constant of about 25. During the deposition of the metal oxide layer 16, several ALD cycles may be carried out to deposit the metal oxide layer 16 with a desired thickness, for example, 1 nm-20 nm.

Likewise, each of the aforesaid ALD cycles for depositing the metal oxide layer 16 includes four sequential stages: (1) flowing organic metal precursor into the reactor for a period of time to adsorb the organic metal precursor over the surface of the substrate; (2) purging the excess organic metal precursor out of the reactor using inert gas such as argon; (3) flowing ozone into the reactor to react the ozone with the organic metal precursor adsorbed on the substrate to form a metal oxide layer; and (4) purging the reactor again with inert gas such as argon. The subsequent ALD cycles repeat the four sequential stages.

Since the carbon electrode layer 12 is covered with the transitional barrier layer 14, the carbon electrode layer 12 is not affected by ozone during the deposition of the metal oxide layer 16. According to the first preferred embodiment of this invention, the transitional barrier layer 14 and the metal oxide layer 16 may be deposited in the same reactor. Different material layers can be deposited in the same reactor by switching different reactant gases. Preferably, the deposition of the transitional barrier layer 14 and the deposition of the metal oxide layer 16 utilize the same organic metal precursor.

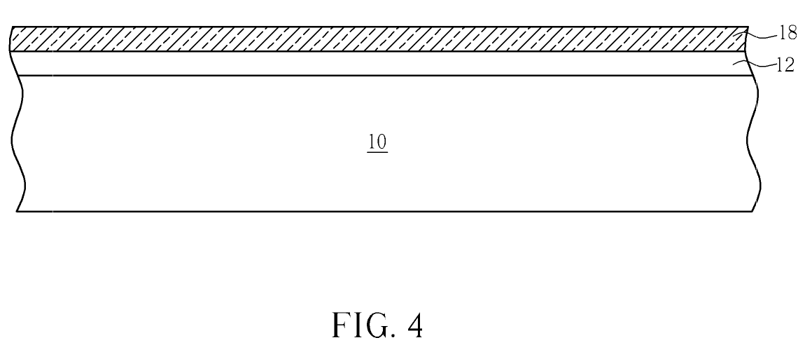

As shown in FIG. 4, the high temperature environment (200° C. ˜600° C.) during the deposition of the metal oxide layer 16 provides adequate energy for reacting the metal oxide layer 16 with the underlying transitional barrier layer 14 to form a metal oxy-nitride layer 18 such as, for example, HfON, having a thickness less than 20 nanometers. According to the first preferred embodiment of this invention, the metal oxy-nitride layer 18 has a dielectric constant that is higher than that of the metal oxide layer 16.

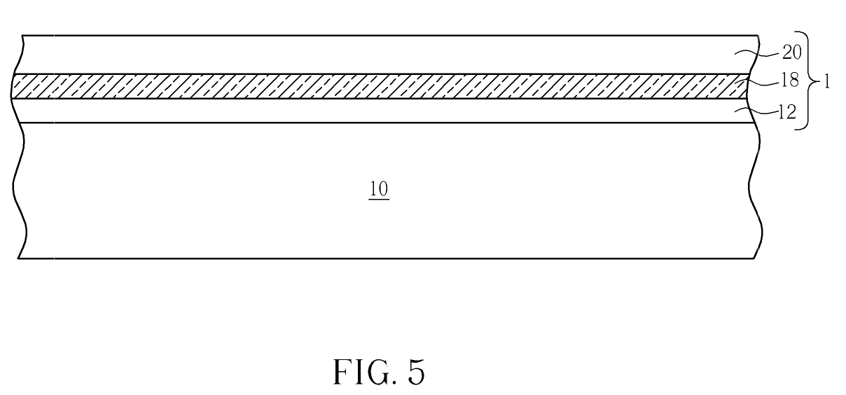

As shown in FIG. 5, subsequently, a top electrode 20 is formed on the metal oxy-nitride layer 18. The top electrode 20 may be a carbon electrode, metal electrode or polysilicon electrode. According to the first preferred embodiment of this invention, the semiconductor capacitor device 1 comprises the carbon electrode layer 12 acting as a bottom capacitor electrode, the metal oxy-nitride layer 18 acting as a capacitor dielectric, and the top electrode 20.

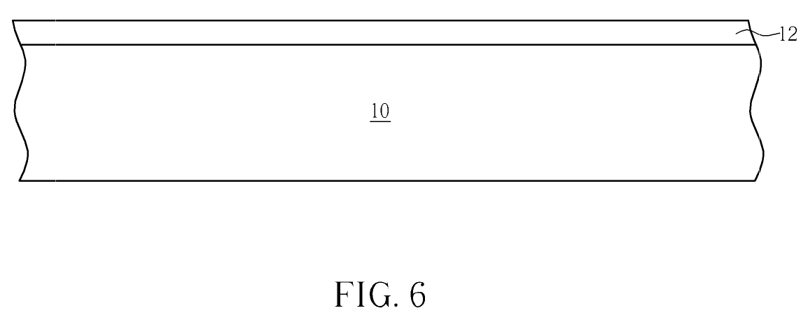

Please refer to FIG.6 to FIG. 9. FIG. 6 to FIG. 9 are schematic, cross-sectional diagrams showing a method for fabricating a semiconductor capacitor device in accordance with the second preferred embodiment of this invention, wherein like numeral numbers designate like layers, regions or parts. As shown in FIG. 6, a substrate 10 such as a silicon substrate is provided. A carbon electrode layer 12 is formed on the substrate 10. The carbon electrode layer 12 acts as a bottom capacitor electrode according to the second preferred embodiment. It is understood that other dielectric layers or devices may be formed on the substrate 10. For the sake of simplicity, these dielectric layers or devices are omitted. The carbon electrode layer 12 may be formed by conventional methods, for example, furnace techniques utilizing ethylene (C₂H₄) as a precursor. The carbon electrode layer 12 is composed of carbon atoms bonded in a conductive manner such as SP2 hybrid orbital bonds. Preferably, the carbon electrode layer 12 has a thickness of about 1 nm-1000 nm.

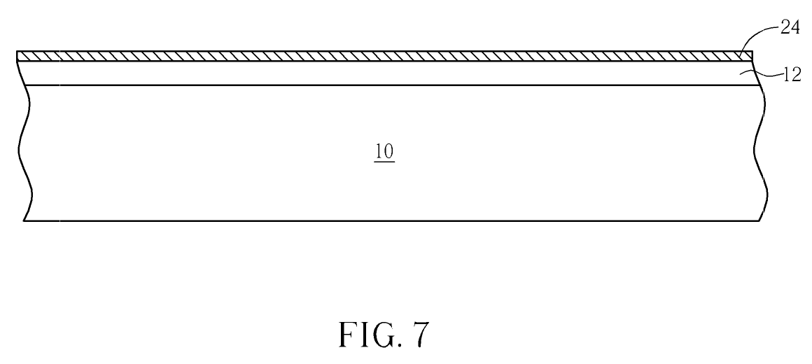

As shown in FIG. 7, after the formation of the carbon electrode layer 12 on the substrate 10, a chemical vapor deposition process is carried out to deposit a dielectric layer 24 on the surface of the carbon electrode layer 12. It is important to cover the entire surface of the carbon electrode layer 12 with the dielectric layer 24. According to the second preferred embodiment of this invention, the dielectric layer 24 may be silicon nitride, silicon oxide or any other suitable high-k dielectric materials.

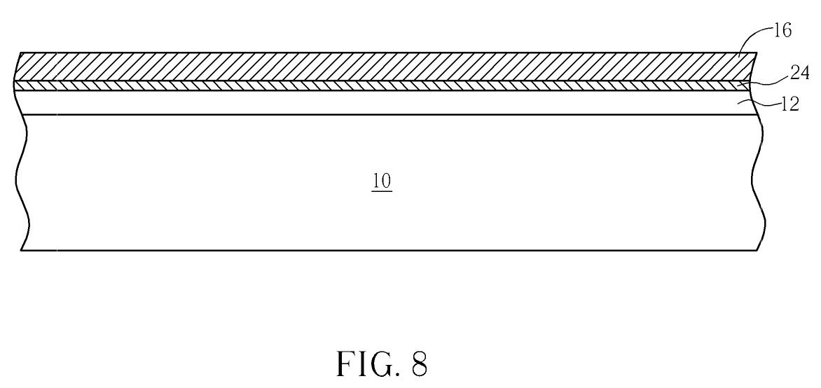

As shown in FIG. 8, after the deposition of the dielectric layer 24 on the carbon electrode layer 12, an ALD process is performed to deposit a metal oxide layer 16 such as aluminum oxide, tantalum oxide, titanium oxide, zirconium oxide, hafnium oxide, lanthanum oxide or cerium oxide on the surface of the dielectric layer 24. The metal oxide layer 16 has high dielectric constant such that the metal oxide layer 16 can function as a capacitor dielectric layer. By way of example, the metal oxide layer 16 is HfO₂ having a dielectric constant of about 25. During the deposition of the metal oxide layer 16, several ALD cycles may be carried out to deposit the metal oxide layer 16 with a desired thickness, for example, 1 nm-20 nm.

Each of the aforesaid ALD cycles for depositing the metal oxide layer 16 includes four sequential stages: (1) flowing organic metal precursor into the reactor for a period of time to adsorb the organic metal precursor over the surface of the substrate; (2) purging the excess organic metal precursor out of the reactor using inert gas such as argon; (3) flowing ozone into the reactor to react the ozone with the organic metal precursor adsorbed on the substrate to form a metal oxide layer; and (4) purging the reactor again with inert gas such as argon. The subsequent ALD cycles repeat the four sequential stages.

Since the carbon electrode layer 12 is covered with the dielectric layer 24, the carbon electrode layer 12 is not affected by ozone during the deposition of the metal oxide layer 16.

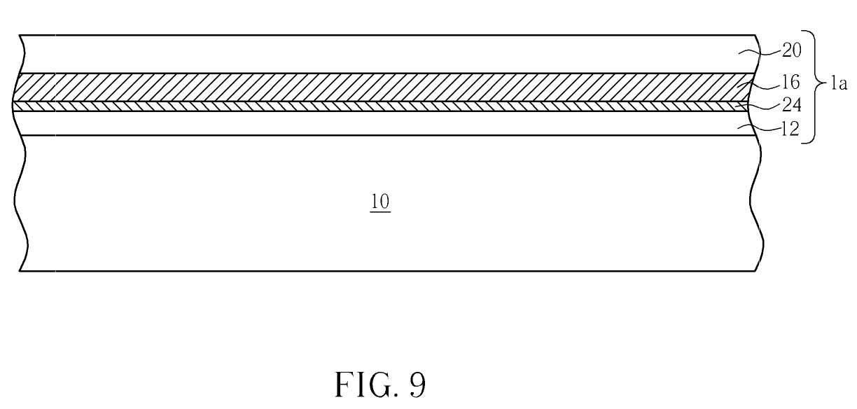

As shown in FIG. 9, subsequently, a top electrode 20 is formed on the metal oxide layer 16. The top electrode 20 may be a carbon electrode, metal electrode or polysilicon electrode. According to the second preferred embodiment of this invention, the semiconductor capacitor device 1a comprises the carbon electrode layer 12 acting as a bottom capacitor electrode, the metal oxide layer 16 acting as a capacitor dielectric, the top electrode 20, and the dielectric layer 24 interposed between the carbon electrode layer 12 and the metal oxide layer 16.

Those skilled in the art will readily observe that numerous modifications and alterations of the device and method may be made while retaining the teachings of the invention.

What is claimed is:

1. A method for fabricating a semiconductor capacitor device, comprising:
providing a substrate;
forming a bottom electrode layer on top of the substrate;
depositing a transitional barrier layer on a surface of the bottom electrode layer;
depositing a metal oxide layer on top of the transitional barrier layer, wherein the transitional barrier layer reacts with the metal oxide layer to form a capacitor dielectric layer; and
forming a top electrode layer on the capacitor dielectric layer.

2. The method according to claim 1 wherein the transitional barrier layer comprises metal nitride.

3. The method according to claim 2 wherein the metal nitride is selected from the group consisting of aluminum nitride, tantalum nitride, titanium nitride, zirconium nitride, hafnium nitride, lanthanum nitride and cerium nitride.

4. The method according to claim 2 wherein the metal oxide layer is selected from the group consisting of aluminum oxide, tantalum oxide, titanium oxide, zirconium oxide, hafnium oxide, lanthanum oxide and cerium oxide.

5. The method according to claim 4 wherein the metal oxide layer deposition process utilizes ozone.

6. The method according to claim 1 wherein the capacitor dielectric layer comprises a metal oxy-nitride layer.

7. The method according to claim 6 wherein the metal oxy-nitride layer has a thickness less than 20 nanometer.

8. The method according to claim 1 wherein the top electrode is selected form the group consisting of carbon electrodes, metal electrodes and polysilicon electrodes.

9. The method according to claim 1 wherein the bottom electrode layer is a carbon electrode layer.

10. The method according to claim 1 wherein the bottom electrode layer deposition process comprises an atomic layer deposition process.

11. The method according to claim 10 wherein the metal oxide layer deposition process comprises an atomic layer deposition process.

12. A method for fabricating a semiconductor capacitor device, comprising:
providing a substrate;
forming a bottom electrode layer on the substrate;
depositing a dielectric layer on a surface of the bottom electrode layer;
performing an atomic layer deposition process to deposit a metal oxide layer on the dielectric layer; and
forming a capacitor top electrode on the metal oxide layer.

13. The method according to claim 12 wherein the metal oxide layer is selected from the group consisting of aluminum oxide, tantalum oxide, titanium oxide, zirconium oxide, hafnium oxide, lanthanum oxide and cerium oxide.

14. The method according to claim 13 wherein the atomic layer deposition process utilizes ozone.

15. The method according to claim 13 wherein the capacitor top electrode is selected from the group consisting of carbon electrode, metal electrode and polysilicon electrode.

16. The method according to claim 15 wherein the dielectric layer comprises silicon nitride and silicon oxide.

17. The method according to claim 12 wherein the bottom electrode layer is a carbon electrode layer.
